(19) United States
(12) Patent Application Publication
(10) Pub. No.: US 2013/0095641 A1
(43) Pub. Date: Apr. 18, 2013

(54) Method Of Manufacturing Gallium Nitride Film

(71) Applicant: Samsung Corning Precision Materials C., Ltd., Gyeongsangbuk-do (KR)

(72) Inventors: SungKeun Lim, ChungCheongNam-Do (KR); Joon Hoi Kim, ChungCheongNam-Do (KR); Boik Park, ChungCheongNam-Do (KR); CheolMin Park, ChungCheongNam-Do (KR); Hyun Jong Park, ChungCheongNam-Do (KR); JunYoung Bae, ChungCheongNam-Do (KR); Seonghwan Shin, ChungCheongNam-Do (KR); WonJo Lee, ChungCheongNam-Do (KR); JunSung Choi, ChungCheongNam-Do (KR); Byungkyu Chung, ChungCheongNam-Do (KR)

(73) Assignee: SAMSUNG CORNING PRECISION MATERIALS CO., LTD., Gyeongsangbuk-do (KR)

(21) Appl. No.: 13/649,719

(22) Filed: Oct. 11, 2012

(30) Foreign Application Priority Data
Oct. 14, 2011 (KR) 10-2011-0105312

(51) Int. Cl. H01L 21/20

(52) U.S. Cl. 438/478; 257/E21.09

(57) ABSTRACT

A method of manufacturing a gallium nitride (GaN) film in which defects in a GaN film that grows can be reduced. The method includes the step of growing a GaN nano-rod on a substrate, the nano-rod having a circumferential groove in an outer periphery thereof, and the step of growing a GaN film on the GaN nano-rod.

### CROSS REFERENCE TO RELATED APPLICATION

The present application claims priority from Korean Patent Application Number 10-2011-0105312 filed on Oct. 14, 2011, the entire contents of which application are incorporated herein for all purposes by this reference.

### BACKGROUND OF THE INVENTION

1. Field of the Invention

The present invention relates to a method of manufacturing a gallium nitride (GaN) film, and more particularly, to a method of manufacturing a GaN film in which defects in a GaN film that grows can be reduced.

2. Description of Related Art

Recently, studies on nitride semiconductors made of aluminum nitride (AlN), gallium nitride (GaN) or indium nitride (InN) as materials for cutting edge devices, such as light-emitting diodes (LEDs) and laser diodes (LDs), are actively underway.

In particular, GaN can generate light in the range from ultraviolet (UV) to blue rays owing to its large transition energy bandwidth. This feature makes GaN an essential next-generation photoelectric material that is used for blue laser diodes (LDs), which are used as light sources for next-generation digital versatile discs (DVDs), white light-emitting diodes (LEDs), which are replacing the existing illumination devices, high-temperature and high-power electronic devices, and the like.

Such compound semiconductors are grown on a heterogeneous substrate made of, for example, sapphire, silicon carbonate (SiC), silicon (Si) or gallium arsenide (GaAs) by hydride vapor phase epitaxy (HVPE), molecular beam epitaxy (MBE), ammonothermal method, sodium (Na) flux method or the like, since they do not have a practical homogeneous substrate.

In particular, the HVPE is a technology enabling the growth of a compound semiconductor that has a relatively great thickness ranging from tens to hundreds of micrometers on a substrate using ammonia, hydrogen and a variety of chloride gases. This technology has an advantage of rapid growth rate, and is most widely used.

When a compound semiconductor substrate which is grown by the HVPE is being grown or being cooled after growth, residual stress occurs inside the compound semiconductor substrate owing to a difference in the coefficient of thermal expansion between the compound semiconductor substrate and a heterogeneous substrate. The residual stress consequently causes the compound semiconductor substrate to bend.

In addition, when the residual stress exceeds the yield strength of the compound semiconductor substrate, cracks occur in the compound semiconductor substrate and radially propagate from the center of the substrate along the cleavage plane.

Such bending and cracking increase defects in the compound semiconductor substrate and worsen the longevity of the compound semiconductor substrate.

In particular, a sapphire substrate of heterogeneous substrates is widely used, since it has a hexagonal structure like GaN, is inexpensive, and is stable at high temperature. However, the differences in the lattice constant (13.8%) and the coefficient of thermal expansion (25.5%) between the sapphire substrate and GaN consequently result in bending and cracking.

FIG. 1 is a graph depicting the ratios of the coefficient of thermal expansion of sapphire, SiC and GaAs when the coefficient of thermal expansion of GaN is set as 1. FIG. 2 is a cross-sectional view depicting bending during growth of a GaN layer, attributable to the difference in the coefficient of thermal expansion between a sapphire substrate 10 and a GaN layer 20. FIG. 3 is a cross-sectional view depicting bending during cooling of the grown GaN layer, attributable to the difference in the coefficient of thermal expansion between the sapphire substrate 10 and the GaN layer 20. Referring to FIG. 1 to FIG. 3, it can be appreciated that the GaN layer is subjected to stress during growth and cooling of the GaN layer owing to the difference in the coefficient of thermal expansion between the sapphire substrate and the GaN layer, thereby causing the GaN layer to bend.

In order to solve such bending and cracking, a variety of technologies have been proposed and employed. For example, a buffer layer which reduces stress is used, or a natural cleaving technology intended to prevent bending which would otherwise occur owing to thermal expansion is used.

However, even in the foregoing methods, cracking or bending occurs during growth and cooling because the heterogeneous substrate and GaN exhibit great differences in the coefficient of thermal expansion and the lattice constant thereof. There is another problem in that cracking occur in the additional process of cleaving the heterogeneous substrate and the GaN layer as residual strain inside the GaN layer is reduced.

The information disclosed in the Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a method of manufacturing a gallium nitride (GaN) film in which defects and cracking attributable to strain are reduced.

In an aspect of the present invention, provided is a method of manufacturing a GaN film which includes the step of growing a GaN nano-rod on a substrate, the nano-rod having a circumferential groove in an outer periphery thereof; and the step of growing a GaN film on the GaN nano-rod.

In an exemplary embodiment, the method may further include the step of, after growing the GaN film, cooling the substrate so that the GaN nano-rod is automatically cleaved at the groove.

In an exemplary embodiment, the substrate may be made of one selected from the group consisting of silicon (Si), silicon carbide (SiC) and gallium arsenide (GaAs).

In an exemplary embodiment, the length and the diameter of the GaN nano-rod may range from 10 nm to 1000 nm.

In an exemplary embodiment, the step of growing the GaN nano-rod may be carried out at a temperature ranging from 500° C. to 700° C.

In an exemplary embodiment, the step of growing the GaN nano-rod may include the steps of growing a first GaN nano-rod; etching an upper end of the first GaN nano-rod; and growing a second GaN nano-rod on the etched upper end of the first GaN nano-rod.

In an exemplary embodiment, the step of etching the upper end of the first GaN nano-rod may be carried out using hydrogen chloride (HCl).

In an exemplary embodiment, the step of growing the GaN nano-rod may include the step of forming a notch-shaped groove in the GaN nano-rod by adjusting a ratio between gallium and nitrogen while the GaN nano-rod is being grown.

In an exemplary embodiment, the step of growing the GaN film may include the step of laterally growing GaN on the upper end of the GaN nano-rod.

In an exemplary embodiment, the step of growing the GaN film may be carried out at a temperature of 900° C. or higher.

In an exemplary embodiment, the step of growing the GaN film may be carried out at a higher temperature than growing the gallium nitride nano-rod.

According to embodiments of the invention, it is possible to facilitate cleavage of the GaN film by efficiently concentrating strain to the groove during the cooling after the growth of the GaN film.

In addition, it is possible to simplify the process of manufacturing the GaN film and increase the yield of the manufacture of the GaN film.

Furthermore, it is possible to reduce the population of defects inside the GaN film that is growing and reduce the occurrence of cracking when cleaving the GaN film that is grown.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a graph depicting the ratios of the coefficient of thermal expansion of sapphire, silicon carbide (SiC) and gallium arsenide (GaAs) when the coefficient of thermal expansion of GaN is set as 1;

FIG. 2 is a cross-sectional view depicting bending during growth of a gallium nitride (GaN) layer, attributable to the difference in the coefficient of thermal expansion between a sapphire substrate and a GaN layer;

FIG. 3 is a cross-sectional view depicting bending during cooling of a GaN layer, attributable to the difference in the coefficient of thermal expansion between a sapphire substrate and a GaN layer;

FIG. 4 is a schematic flowchart depicting a method of manufacturing a GaN film according to an embodiment of the invention; and

FIG. 5 and FIG. 6 are schematic conceptual views depicting a method of manufacturing a GaN film according to an embodiment of the invention.

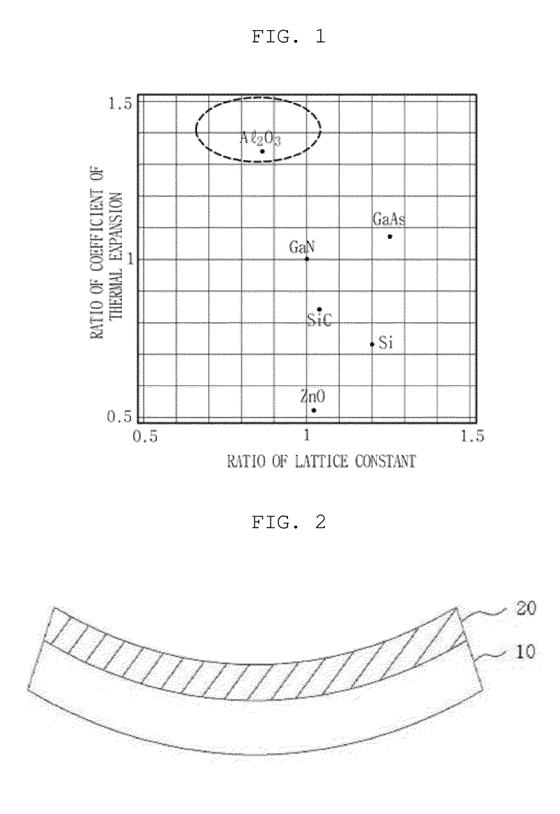

### DETAILED DESCRIPTION OF THE INVENTION

Reference will now be made in detail to a method of manufacturing a gallium nitride (GaN) film of the present invention, embodiments of which are illustrated in the accompanying drawings and described below.

In the following description of the present invention, detailed descriptions of known functions and components incorporated herein will be omitted when they may make the subject matter of the present invention unclear.

A GaN nano-rod according to an embodiment of the invention can have changes in diameter. For example, the nano-rod has a neck the diameter of which is smaller than that of a proximal section such that the GaN nano-rod can be cleaved at the neck.

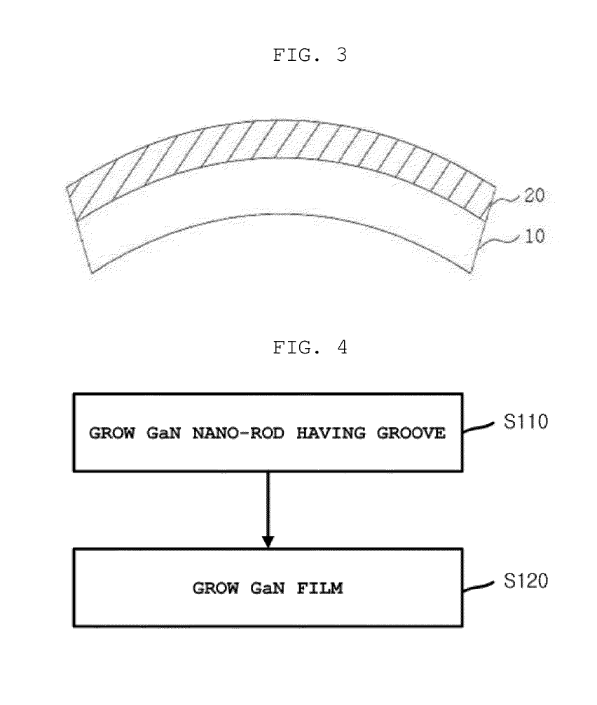

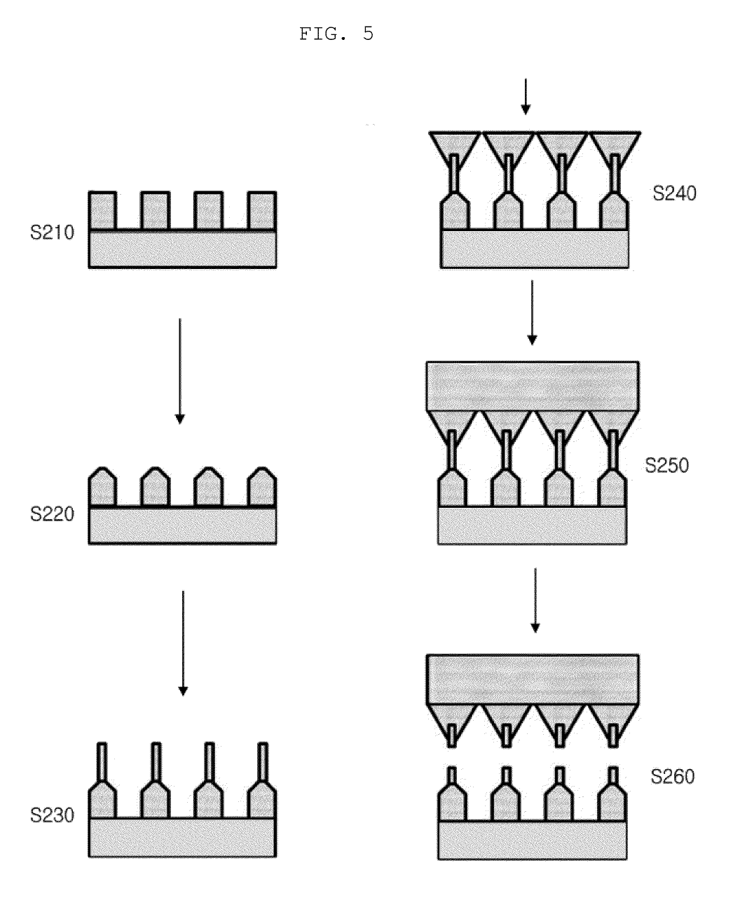

FIG. 4 is a schematic flowchart depicting a method of manufacturing a GaN film according to an embodiment of the invention.

Referring to FIG. 4, the method of manufacturing a GaN film according to an embodiment of the invention includes the step of growing a GaN nano-rod having a groove and the step of growing a GaN film.

In order to manufacture the GaN film, first, at S110, a GaN nano-rod having a groove is grown on a heterogeneous substrate.

The heterogeneous substrate may be made of one selected from among silicon (Si), silicon carbide (SiC) and gallium arsenide (GaAs). The heterogeneous substrate of the present invention is not limited thereto, but can be made of a variety of materials that are generally used in the art.

The GaN nano-rod can be grown by growing GaN in the vertical direction by blowing a reactant gas which contains Ga, ammonia (NH₃) and the like into a reactor in which the heterogeneous substrate is disposed.

More specifically, when the partial pressure of the reactant gas is saturated in response to the adjustment of the partial pressure and temperature of the reactant gas, the type of chemical deposition is converted from heterogeneous nucleation mode into homogeneous nucleation mode, and nano-particles grow on the heterogeneous substrate. A seed layer is formed from these nano-particles as sintering is carried out and recrystallization is obtained.

The sintering may be substituted with annealing in order to form the seed layer. The size of nano-particles and grain boundaries can be controlled depending on the temperature and time for forming the seed layer.

Based on the seed layer, a nano-rod is spontaneously formed and grows in the vertically upward direction.

It is preferred that the temperature for growing the GaN nano-rod range from 500° C. to 700° C. When the temperature is below 500° C., the sintering of nano-particles is not efficient and thus the nano-rod may not be properly formed. When the temperature exceeds 700° C., the nano-rod may not be properly formed but is deposited in the shape of a thin film.

It is preferred that the length and diameter of the GaN nano-rod that is to be grown range from 10 nm to 1000 nm.

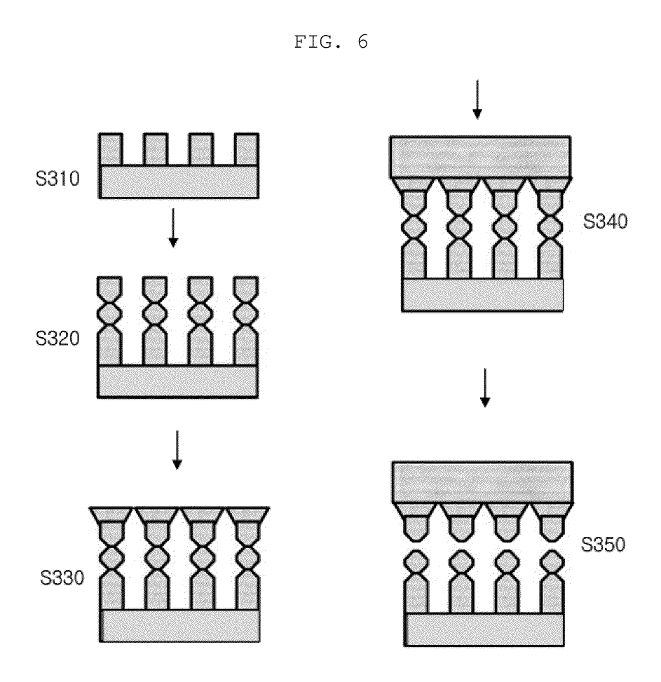

As shown in FIG. 5, the GaN nano-rod which has a circumferential groove in the outer periphery thereof can be manufactured by step S210 of growing a first GaN nano-rod on the substrate, step S220 of surface-treating the upper end of the first GaN nano-rod via etching so that the upper end becomes sharp, and S230 of growing a second GaN nano-rod on the sharpened upper end.

Here, the upper end of the first GaN nano-rod can be etched using HCl gas.

Alternatively, as shown in FIG. 6, the GaN nano-rod which has a circumferential groove in the outer periphery thereof can be manufactured by step S310 of growing the GaN nano-rod on the substrate and step S320 of forming a notch-shaped groove in the GaN nano-rod by adjusting the ratio between Ga and nitrogen (N) while growing the GaN nano-rod on the substrate at step S310. If the ratio of N to Ga is high, the GaN nano-rod will be thin. If the ratio of N to Ga is low, the GaN nano-rod will be thick.

The thickness of the GaN nano-rod which is to be grown varies depending on the reaction ratio between Ga and N. Based on that fact, it is possible to manufacture the GaN nano-rod which has the notch-shaped groove in the outer periphery thereof.

Since the GaN nano-rod has the circumferential groove in the outer periphery thereof, it is possible to concentrate the effect of strain to the groove during cooling after the GaN has been grown, thereby facilitating cleaving of the GaN film.

As for a GaN nano-rod without a groove, a separate cleaving process is carried out in order to cleave the GaN film after the GaN film has been grown and cooled. Otherwise, the GaN nano-rod is cut by growing the GaN film to be thick such that stress is accumulated in the GaN nano-rod.

However, in the present invention, strain is concentrated to the groove which is formed in the GaN nano-rod. Consequently, even though the thickness of the grown GaN film which has the groove is smaller than that of a GaN nano-rod without the groove, the GaN nano-rod which has the groove can be automatically cleaved at the groove.

Finally, at S120, a GaN film is grown on the GaN nano-rod having the groove by a conventional method, thereby producing a GaN film. GaN is laterally grown on the upper end of the GaN nano-rod which has the groove, thereby producing the GaN film.

The step of growing the GaN film can be carried out at a temperature of 900° C. or higher.

In this fashion, unlike the method of growing a GaN film on a heterogeneous substrate of the related art, the GaN film is grown on the GaN nano-rod which does not have a structural defect and can effectively alleviate strain. It is therefore possible to reduce the population of defects inside the GaN film which is growing. In addition, it is possible to reduce the occurrence of cracking when cleaving the GaN film which is grown since the stress of the GaN film is alleviated.

In addition, after the step of growing the GaN film, the method of manufacturing a GaN film of this embodiment can further include step S260, S350 of cooling the substrate on which the GaN film has been grown at room temperature so that strain is concentrated to the groove of the GaN nano-rod as described above, thereby automatically cleaving the GaN nano-rod at the groove.

Since the GaN nano-rod is automatically cleaved, laser lift-off processing of the related art is not required. Consequently, it is possible to simplify the process of manufacturing the GaN film and thus prevent the yield from lowering at the laser lift-off processing.

The foregoing descriptions of specific exemplary embodiments of the present invention have been presented with respect to the certain embodiments and drawings. They are not intended to be exhaustive or to limit the invention to the precise forms disclosed, and obviously many modifications and variations are possible for a person having ordinary skill in the art in light of the above teachings.

It is intended therefore that the scope of the invention not be limited to the foregoing embodiments, but be defined by the Claims appended hereto and their equivalents. ( [symbol] )

What is claimed is:

1. A method of manufacturing a gallium nitride film, comprising:
growing a gallium nitride (GaN) nano-rod on a substrate, the nano-rod having a circumferential groove in an outer periphery thereof; and
growing a gallium nitride film on the gallium nitride nano-rod.

2. The method of claim 1, further comprising, after growing the gallium nitride film, cooling the substrate so that the gallium nitride nano-rod is automatically cleaved at the groove.

3. The method of claim 1, wherein the substrate is made of one selected from the group consisting of silicon (Si), silicon carbide (SiC) and gallium arsenide (GaAs).

4. The method of claim 1, wherein a length and a diameter of the gallium nitride nano-rod range from 10 nm to 1000 nm.

5. The method of claim 1, wherein growing the gallium nitride nano-rod is carried out at a temperature ranging from 500° C. to 700° C.

6. The method of claim 1, wherein growing the gallium nitride nano-rod comprises:
growing a first gallium nitride nano-rod;
etching an upper end of the first gallium nitride nano-rod; and
growing a second gallium nitride nano-rod on the etched upper end of the first gallium nitride nano-rod.

7. The method of claim 6, wherein etching the upper end of the first gallium nitride nano-rod is carried out using hydrogen chloride (HCl).

8. The method of claim 1, wherein growing the gallium nitride nano-rod comprises forming a notch-shaped groove in the gallium nitride nano-rod by adjusting a ratio between gallium and nitrogen while the gallium nitride nano-rod is being grown.

9. The method of claim 1, wherein growing the gallium nitride film comprises laterally growing gallium nitride on the upper end of the gallium nitride nano-rod.

10. The method of claim 1, wherein growing the gallium nitride film is carried out at a temperature of 900° C. or higher.

11. The method of claim 1, wherein growing the gallium nitride film is carried out at a higher temperature than growing the gallium nitride nano-rod.
